(19) United States
(12) Patent Application Publication
(10) Pub. No.: US 2025/0076185 A1
(43) Pub. Date: Mar. 6, 2025

(54) Angle Of Incidence And Azimuth Angle Resolved Spectroscopic Ellipsometry For Semiconductor Metrology

(71) Applicant: KLA Corporation, Milpitas, CA (US)

(72) Inventors: Janardan Nath, Milpitas, CA (US); Shankar Krishnan, Cupertino, CA (US); Harish Kashyap, Milpitas, CA (US)

(21) Appl. No.: 18/812,890

(22) Filed: Aug. 22, 2024

Related U.S. Application Data
(60) Provisional application No. 63/535,581, filed on Aug. 31, 2023.

(51) Int. Cl. G01N 21/21

(52) U.S. Cl. CPC G01N 21/211; G01N 2021/213

(57) ABSTRACT

Methods and systems for performing spectroscopic ellipsometry (SE) measurements of semiconductor structures based on data sets resolved in wavelength, azimuth angle, and angle of incidence are presented herein. In some embodiments, machine learning based measurement models are trained to infer estimated values of one or more parameters of interest characterizing a structure under measurement based on SE measurement data resolved in wavelength, azimuth angle, and angle of incidence. In some other embodiments, regression is performed on a physics based measurement model to estimate values of one or more parameters of interest characterizing a structure under measurement. A dispersive element in the collection beam path disperses collected light across the active surface of a detector to resolve collected light according to wavelength and one angular dimension. Furthermore, multiple images are collected by the detector to resolve collected light across the other angular dimension.

### CROSS REFERENCE TO RELATED APPLICATION

The present application for patent claims priority under 35 U.S.C. § 119 from U.S. provisional patent application Ser. No. 63/535,581 entitled “Angle of incidence (AOI), Azimuth (Az) and Wavelength Resolved Ellipsometric-Spectroscopy Method,” filed Sep. 1, 2023, the subject matter of which is incorporated herein by reference in its entirety.

### TECHNICAL FIELD

The described embodiments relate to metrology systems and methods, and more particularly to methods and systems for improved measurement of semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to measure defects on wafers to promote higher yield. Optical metrology techniques offer the potential for high throughput without the risk of sample destruction. A number of optical metrology based techniques including scatterometry, ellipsometry, and reflectometry implementations and associated analysis algorithms are commonly used to characterize critical dimensions, film thicknesses, composition, overlay and other parameters of nanoscale structures.

Flash memory and dynamic random access memory (DRAM) architectures are transitioning from two dimensional floating-gate architectures to fully three dimensional geometries. In some examples, film stacks and etched structures are very deep (e.g., up to fifteen micrometers in depth, or more), and include many layers. For example, state of the art NAND memory structures include 200-300 layers, and are trending toward more layers, e.g., 300-1,000 layers. Such high aspect ratio, multiple layer structures create challenges for film and CD measurements. The ability to measure the critical dimensions that define the shapes of holes and trenches of these structures is critical to achieve desired performance levels and device yield. In addition, many semiconductor architectures employ thick, opaque material layers such as amorphous-carbon layers, tungsten layers, and hard mask layers.

Many optical techniques suffer from low signal-to-noise ratios (SNRs), as only a small fraction of the illumination light is able to reach the bottom of high aspect ratio features, and reflect upwards to the detector. In particular, illumination light in the vacuum ultraviolet, ultraviolet, visible, and short infrared wavelength ranges (i.e., wavelengths below approximately 1 micrometer) suffer from low SNR, and in some examples, do not sufficiently penetrate the opaque layers, resulting in no measureable signal at all. Thus, many available high-throughput metrology techniques are unable to reliably perform CD and film measurements of high aspect ratio structures.

Critical dimension, small angle X-ray scatterometry (CD-SAXS), normal incidence reflectometry, and scatterometry are being explored as measurement solutions for high aspect ratio structures, but development is still on-going. Cross-sectional scanning electron microscopy (SEM) is a low throughput, destructive technique that is not suitable for inline metrology. Atomic force microscopy (AFM) is limited in its ability to measure high aspect ratio structures and has relatively low throughput. CD-SAXS has not yet been demonstrated to achieve high throughput capabilities required by the semiconductor industry. Model based infrared reflectometry (MBIR) has been used for metrology of high aspect ratio DRAM structures, but the technique lacks the resolution provided by shorter wavelengths and the measurement spot sizes are too large for semiconductor metrology. See “Measuring deep-trench structures with model-based IR,” by Gostein et al., Solid State Technology, vol. 49, no. 3, Mar. 1, 2006, which is incorporated by reference as if fully set forth herein.

Spectroscopic Reflectometry (SR), or a mix of SR with Interferometry, is able to perform measurements in a few, special-case measurement applications at a small number of process steps. Unfortunately, these techniques lack the sensitivity required to measure critical dimensions, shape profiles, or film thickness at a large number of critical process steps.

Existing Spectroscopic Ellipsometry (SE) based optical metrology tools are limited in their ability to measure high aspect ratio structures, particularly 3D NAND having more than 300 layers and 3D DRAM greater than 10 micrometers deep.

In conventional ellipsometry, the change in polarization after reflection from a surface is measured. Advanced ellipsometry systems often incorporate a rotating polarizer in the illumination beam path and a rotating analyzer in the collection beam path. Generally, image data is collected on a detector and subjected to a Fourier transformation. The transformed image data results in a harmonic signal representation of the collected data. In some examples, the harmonic signal representation is parameterized in terms of harmonic parameters, alpha and beta.

In some examples, light scattered from a die under measurement is detected by a pixelated, two dimensional detector. Each pixel of the detector measures the photon intensity incident at the pixel. In some examples, the two dimensional image includes photon intensity data resolved in one dimension according to wavelength and resolved in another dimension according to azimuth angle. FIG. 1 depicts an illustration of a scattering image 10 captured by a detector of a SE system. As depicted in FIG. 1, scattering image 10 is resolved in accordance with wavelength in the X-direction and in accordance with azimuth angle in the Y-direction. Traditionally, the resolved two-dimensional image data is integrated, i.e., binned, in the azimuth angle direction, and the resulting signal is subjected to Fourier transformation to calculate harmonic parameters, e.g., spectroscopic ellipsometry parameters alpha and beta, or Mueller Matrix coefficients, etc.

FIG. 2 depicts an illustration of a plot 20 of scattering intensity as a function of wavelength. Plot 20 is calculated by integrating, i.e., binning, scattering image 10 in the azimuth angle direction, i.e., the photon intensity of each column of pixels depicted in FIG. 1 is summed to obtain the corresponding intensity data point associated with each wavelength depicted in plot 20. Unfortunately, signal information is lost when integration is performed to compress the data set to a one dimensional spectroscopic data set from which typical spectroscopic ellipsometry parameters are derived. As depicted in FIG. 2, integrating across the azimuth angle dimension of the two dimensional data set yields a useful spectrum, but it sacrifices the complete signal information available from scattering image 10.

Furthermore, in typical SE measurement systems, illumination light is provided to a die under measurement at or near the Brewster angle of incidence (approximately 65 degrees from a normal to the wafer surface). Moreover, a collection mask is typically employed to selectively capture light at a single collection NA about the Brewster angle of incidence. In some examples, a two dimensional image includes photon intensity data resolved in one dimension according to wavelength and resolved in another dimension according to angle of incidence. Traditionally, the resolved two-dimensional image data is integrated, i.e., binned, in the angle of incidence direction, and the resulting signal is subjected to Fourier transformation to calculate harmonic parameters, e.g., spectroscopic ellipsometry parameters alpha and beta, or Mueller Matrix coefficients, etc. Again, this approach provides a useful spectral signal, but it sacrifices the complete signal information available from multiple angles of incidence.

In general, current spectroscopic ellipsometry systems discard signal information to enable calculation of physical model based optical parameters, such as signal harmonic parameters, Mueller Matrix elements, etc.

However, ongoing reductions in feature size, increasing depths and layers of structural features, and increasing use of opaque material layers impose difficult requirements on optical metrology systems. Optical metrology systems must meet high precision and accuracy requirements for increasingly complex targets at high throughput to remain cost effective. In this context, lost signal information has emerged as a performance limiting issue in the design of optical metrology systems suitable for high aspect ratio structures with a relatively large number of layers, e.g., over 300 layers. Thus, improved metrology systems and methods to overcome these limitations are desired.

### SUMMARY

Methods and systems for performing spectroscopic ellipsometry (SE) measurements of semiconductor structures based on data sets resolved in wavelength, azimuth angle, and angle of incidence are presented herein. In some embodiments, machine learning based measurement models are trained to infer estimated values of one or more parameters of interest characterizing a structure under measurement based on SE measurement data resolved in wavelength, azimuth angle, and angle of incidence. In some other embodiments, regression is performed on a physics based measurement model to estimate values of one or more parameters of interest characterizing a structure under measurement.

In one aspect, a spectroscopic ellipsometry based measurement system employs angle-resolved detection to realize a small measurement box size and high spectral signal resolution to maintain measurement sensitivity over a range of wavelengths. Angle-resolved detection of the collection NA in both AOI and Az increases available signal information and enhances measurement capability, e.g., accuracy, precision, stability, while maintaining a small measurement box-size. Angle-resolved detection of the collection NA provides a relatively large dimension data set associated with each measurement. This relatively large data set is sensitive to variations of geometry of very small featured buried deep within measured structures.

A dispersive element in the collection beam path disperses collected light across the active surface of a detector in two dimensions. In some embodiments, a dispersive element disperses the collected light according to wavelength across the active surface of the detector along one direction, and disperses the collected light according to angle of incidence across the active surface of the detector along another direction. In other embodiments, the dispersive element disperses the collected light according to wavelength across the active surface of the detector along one direction, and disperses the collected light according to azimuth angle across the active surface of the detector along another direction.

In a further aspect, a spectroscopic metrology system includes a positioning subsystem configured to rotate the dispersive element about a first axis in-plane with the planar, two-dimensional surface of the at least one detector and aligned with a blaze direction of the dispersive element and rotate the dispersive element about a second axis in-plane with the planar, two-dimensional surface of the at least one detector and orthogonal to the first axis. In some embodiments, a positioning subsystem orients the dispersive element about one axis such that the dispersive element scans through the collection NA over the range of collection AOI or AZ, and scans the dispersed beam onto detector. In this manner, each image detected by the detector includes photon intensity data resolved in wavelength in one direction and AOI or Az in another direction. In a further aspect, the spectroscopic metrology system is configured to generate a set of multiple images indicative of the detected light resolved in wavelength, AOI, and Az.

In some embodiments, each image detected by the detector includes photon intensity data resolved in wavelength in one direction and AOI in another direction. In addition, the positioning subsystem reorients the dispersive element about another axis to sample a set of different azimuth angles over the range of collection azimuth angles. An image is detected by the detector at each different azimuth angle, and each detected image captures photon intensity data resolved in wavelength in the one direction and AOI in another direction.

In some other embodiments, each image detected by the detector includes photon intensity data resolved in wavelength in one direction and Az in another direction. In addition, the positioning subsystem reorients the dispersive element about another axis to sample a set of different angles of incidence over the range of collection angles of incidence. An image is detected by the detector at each different angle of incidence, and each detected image captures photon intensity data resolved in wavelength in one direction and Az in another direction.

In a further aspect, a subset of each image of a set of measured images resolved in AOI, Az, and wavelength is selected as input to a measurement model employed to estimate a value of a parameter of interest. In some examples, the subset of each image is selected to capture signal information associated with a smaller NA than the available NA associated with the entire collected image. It may be preferable to estimate values of one or more parameters of interest based on signal information associated with a smaller NA to effectively reduce the illumination spot size to fit smaller measurement targets.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a depiction of a scattering image 10 captured by a detector of a SE system.

FIG. 2 is a plot illustrative of scattering intensity as a function of wavelength calculated by integrating scattering image 10, depicted in FIG. 1, in the azimuth angle direction.

FIG. 3 depicts an exemplary metrology system 100 for performing spectroscopic measurements of semiconductor structures based on data sets resolved in wavelength, azimuth angle, and angle of incidence as described herein.

FIG. 4 is a simplified diagram illustrative of a AOI and Azimuth resolved spectroscopic measurement engine 150 in one embodiment.

FIG. 5 is a simplified diagram illustrative of a AOI and Azimuth resolved spectroscopic measurement model training engine 160 in one embodiment.

FIG. 6 is a simplified diagram illustrative of an active surface of a detector of a metrology system for performing spectroscopic measurements of semiconductor structures as described herein.

FIG. 7 is a simplified illustration of an exemplary high aspect ratio semiconductor structure 170 that suffers from low light penetration into the structure(s) being measured.

FIG. 8 depicts an embodiment 180 of a combined illumination source.

FIG. 9A depicts another embodiment 200 of a combined illumination source.

FIG. 9B depicts another embodiment 220 of a combined illumination source.

FIG. 9C depicts another embodiment 240 of a combined illumination source.

FIG. 10 depicts a plot illustrative of the specific detectivity of various detector technologies operating at specified temperatures.

FIG. 11 depicts an illustration of a multi-zone infrared detector 270.

FIG. 12 illustrates typical photosensitivity curves of four available Indium Gallium Arsenide (InGaAs) sensors.

FIG. 13 illustrates a method 400 of performing spectroscopic measurements of one or more structures based on data sets resolved in wavelength, azimuth angle, and angle of incidence as described herein.

### DETAILED DESCRIPTION

Reference will now be made in detail to background examples and some embodiments of the invention, examples of which are illustrated in the accompanying drawings.

Methods and systems for performing spectroscopic ellipsometry (SE) measurements of semiconductor structures based on data sets resolved in wavelength, azimuth angle, and angle of incidence are presented herein. In some embodiments, machine learning based measurement models are trained to infer estimated values of one or more parameters of interest characterizing a structure under measurement based on SE measurement data resolved in wavelength, azimuth angle, and angle of incidence. In some other embodiments, regression is performed on a physics based measurement model to estimate values of one or more parameters of interest characterizing a structure under measurement. The methods and systems described herein do not involve integration, i.e., binning, across measurement data resolved in azimuth angle, angle of incidence, or both, thus avoiding loss of signal information inherent to integration. Rather, the measurement model operates on a measurement data set resolved in wavelength, azimuth angle, and angle of incidence, e.g., measurement data set includes measured photon intensity as a function of wavelength, azimuth angle, and angle of incidence.

In one aspect, a spectroscopic ellipsometry based measurement system employs angle-resolved detection to realize a small measurement box size, e.g., less than 70 micrometers, and high spectral signal resolution to maintain measurement sensitivity over a range of wavelengths from 170 nanometer to 2, 000 nanometers, 170 nanometer to 2,500 nanometers, or greater. Angle-resolved detection of the collection NA in both AOI and Az increases available signal information and enhances measurement capability, e.g., accuracy, precision, stability, while maintaining a small measurement box-size. Angle-resolved detection of the collection NA in both AOI and Az enables desired measurement box-size and signal resolution requirements for deep structures at current and future semiconductor manufacturing nodes. Angle-resolved detection of the collection NA provides a relatively large dimension data set associated with each measurement. This relatively large data set is sensitive to variations of geometry of very small featured buried deep within measured structures. Without angle-resolved detection of the collection NA, the total collection NA is unresolved, i.e., the detected intensity associated with the entire collection NA is aggregated into a single value. This relatively small data set is either insensitive to variations of many different geometric features buried deep within measured structures or is computationally unstable due to a lack of sensitivity to the parameters of interest.

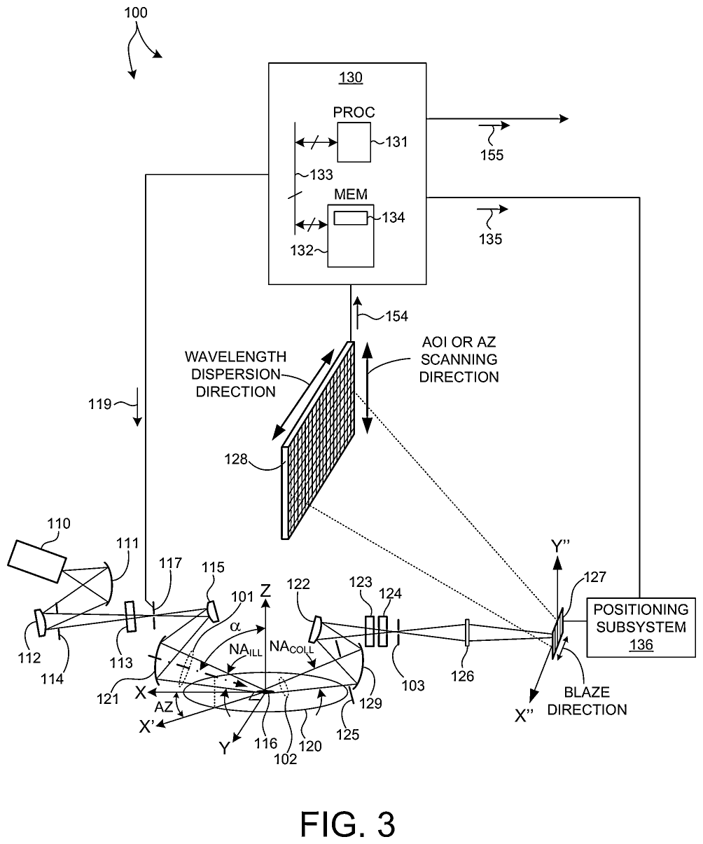

FIG. 3 depicts an exemplary, metrology system 100 for performing spectroscopic measurements of semiconductor structures (e.g., film thickness, critical dimensions, overlay, etc.). As depicted in FIG. 3, metrology system 100 is configured as an oblique incidence, spectroscopic ellipsometer. However, in general, metrology system 100 may also include additional spectroscopic ellipsometers, a spectroscopic reflectometer, scatterometer, or any combination thereof.

Metrology system 100, depicted in FIG. 3, includes an illumination source 110 that generates a beam of illumination light 101 incident on a wafer 120. Illumination source 110 includes one or more illumination sources that emit illumination light including wavelengths in a range from 170 nanometers to 2,500 nanometers. In some embodiments, illumination source 110 is a single illumination source, e.g., laser sustained plasma (LSP) light source (a.k.a., laser driven plasma source) or arc lamp source, that emits illumination light in the ultraviolet, visible, and infrared spectra, including ultraviolet wavelengths down to 170 nanometers and infrared wavelengths greater than two micrometers, e.g., illumination wavelengths ranging from 170 nanometers to 2,500 nanometers. In some other embodiments, illumination source 110 is a combined illumination source that emits illumination light in the ultraviolet, visible, and infrared spectra, including ultraviolet wavelengths down to 170 nanometers and infrared wavelengths greater than two micrometers, e.g., illumination wavelengths ranging from 170 nanometers to 2,500 nanometers. In some other embodiments, illumination source 110 is a combined illumination source that emits illumination light including wavelengths in a range from 170 nanometers to 7,000 nanometers.

In some embodiments, illumination source 110 includes a supercontinuum laser source and a laser sustained plasma light source. The supercontinuum laser source provides illumination at wavelengths greater than 400 nanometers, and in some embodiments, up to 5 micrometers, or more. The laser sustained plasma (LSP) light source (a.k.a., laser driven plasma source) produces photons across the entire wavelength range from 170 nanometers to 2500 nanometers, and beyond. The pump laser of the LSP light source may be continuous wave or pulsed. In some embodiments, combined illumination source 110 includes a supercontinuum laser source and an arc lamp, such as a Xenon arc lamp. However, a laser-driven plasma source produces significantly more photons than a Xenon lamp across the entire wavelength range from 170 nanometers to 2500 nanometers, and is therefore preferred.

Combined illumination source 110 includes a combination of a plurality of broadband or discrete wavelength light sources. The light generated by combined illumination source 110 includes a continuous spectrum or parts of a continuous spectrum, from ultraviolet to infrared (e.g., vacuum ultraviolet to long infrared). In general, combined illumination light source 110 may include a supercontinuum laser source, an infrared helium-neon laser source, a silicon carbide globar light source, a tungsten halogen light source, one or more infrared LEDS, one or more infrared lasers or any other suitable infrared light source generating wavelengths greater than two micrometers, and an arc lamp (e.g., a Xenon arc lamp), a deuterium lamp, a LSP light source, or any other suitable light source generating wavelengths in a range from 170 nanometers to 2,000 nanometers, 170 nanometers to 2,500 nanometers, or greater.

In general, combined illumination source 110 includes multiple illumination sources optically coupled in any suitable manner. In some embodiments, light emitted by a supercontinuum laser source is directly coupled through the plasma generated by the ultraviolet/visible light source.

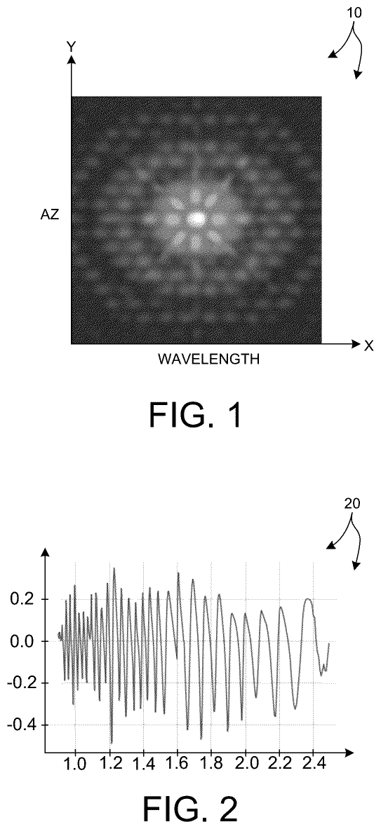

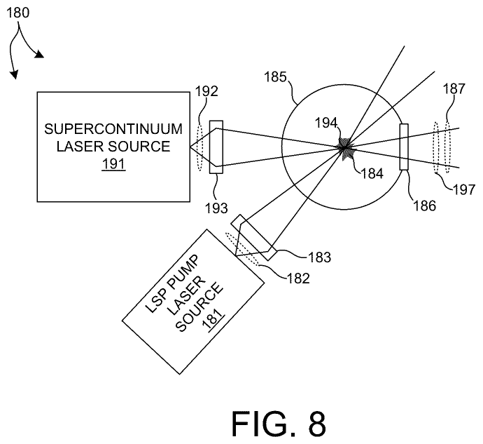

FIG. 8 depicts an embodiment 180 of a combined illumination source 110. As depicted in FIG. 8, a LSP pump laser source 181 generates pump light 182 that is focused by focusing optics 183 to sustain a plasma 184 contained by bulb 185. Plasma 184 generates broadband spectrum light over a wavelength range of ultra-violet to short infrared. Bulb 185 includes an exit port 186. LSP output light 187 is the portion of light from plasma 184 that passes through exit port 186 and is directed towards the illumination optics subsystem as described with reference to FIG. 1. In addition, supercontinuum laser source 191 generates infrared light 192 that is focused by focusing optics 193 to a focus 194 at or near plasma 184. Supercontinuum output light 197 is the portion of light from the focus 194 that passes through exit port 186 and is directed towards the illumination subsystem as described with reference to FIG. 3. In one example, the LSP output light 187 and supercontinuum output light 197 are co-located. In this manner, infrared light 197 from supercontinuum source 191 is effectively combined with ultraviolet/visible light 187 from LSP laser source 181. In one example, LSP output light 187 and supercontinuum output light 197 have the same or similar illumination numerical aperture. In another example, LSP output light 187 and supercontinuum output light 197 have different illumination numerical aperture. In some examples, bulb 185 is constructed from Calcium Fluoride or Magnesium Fluoride to transmit wavelengths above 2.5 micrometers generated by supercontinuum laser source 191. In some other examples, bulb 185 includes one or more exit ports 186 fabricated from Calcium Fluoride or Magnesium Fluoride to transmit wavelengths above 2.5 micrometers generated by supercontinuum laser source 191. A conventional bulb constructed from fused silica does not transmit significant light above 2.5 micrometers, and is thus unsuitable for combining light generated by the supercontinuum laser source 191 in the manner described herein. In some embodiments, the LSP pump laser source 181 is a continuous wave laser. In some other embodiments, the LSP pump laser source 181 is a pulsed laser.

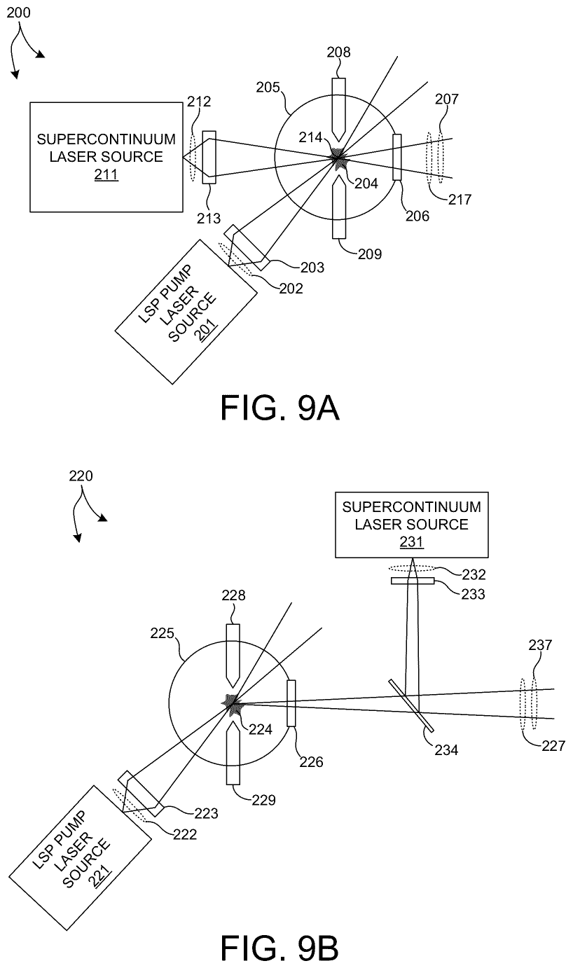

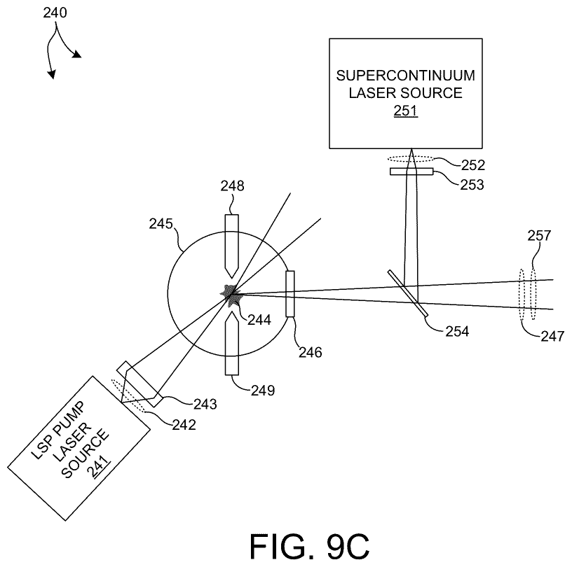

FIG. 9A depicts an embodiment 200 of a combined illumination source 110. As depicted in FIG. 9A, a voltage provided across a cathode 208 and an anode 209 generates a plasma 204 contained by bulb 205. In addition, a LSP pump laser source 201 generates pump light 202 that is focused by focusing optics 203 to sustain plasma 204 contained by bulb 205. Plasma 204 generates broadband spectrum light over a wavelength range of ultra-violet to short infrared. Ultraviolet/visible/short infrared light 207 generated by plasma 204 is provided to the illumination optics subsystem as described with reference to FIG. 3. In addition, supercontinuum laser source 211 generates infrared light 212. Infrared light 212 is focused by focusing lens 213 and forms a focus 214 at or near plasma 204. Infrared light 217 from focus 214 is provided to the illumination optics subsystem as described with reference to FIG. 3. In one example, UV/visible/short infrared light 207 and infrared light 217 are co-located and are effectively combined. In some examples, bulb 205 is constructed from Calcium Fluoride or Magnesium Fluoride to transmit wavelengths above 2.5 micrometers generated by supercontinuum laser source 211. In some other examples, bulb 205 includes one or more exit ports 206 fabricated from Calcium Fluoride or Magnesium Fluoride to transmit wavelengths above 2.5 micrometers generated by supercontinuum laser source 211. A conventional bulb constructed from fused silica does not transmit significant light above 2.5 micrometers, and is thus unsuitable for combining light generated by the supercontinuum laser illumination source 211 in the manner described herein.

FIG. 9B depicts an embodiment 220 of a combined illumination source 110. As depicted in FIG. 9B, a voltage provided across a cathode 228 and an anode 229 generates a plasma 224 contained by bulb 225. In addition, a LSP pump laser source 221 generates pump light 222 that is focused by focusing optics 223 to sustain plasma 224 contained by bulb 225. Plasma 224 generates broadband spectrum light over a wavelength range of ultra-violet to short infrared. Ultraviolet/visible/short infrared light 227 generated by plasma 224 exits bulb 225 through exit port 226 and is provided to the illumination optics subsystem as described with reference to FIG. 3. In addition, supercontinuum laser source 231 generates infrared light 232. Infrared light 232 is focused by focusing lens 233. Infrared light 237 from supercontinuum laser source 231 is provided to the illumination optics subsystem as described with reference to FIG. 3.

As depicted in FIG. 9B, UV/visible/short infrared light 227 and infrared light 237 are combined by beam combiner 234. As such, beam combiner 234 combines light generated by an ultraviolet light source 221 (e.g., LSP light source 221) with light generated by an infrared light source 231 (e.g., supercontinuum laser light source 231). In one example, the beam combiner 234 has a splitting wavelength, for example, at or near 900 nanometers. The beam combiner minimizes loss of light generated by the LSP light source (LSP loss less than 10%) and minimizes depolarization effects (e.g., less than 0.1%) across all illumination wavelengths.

FIG. 9C depicts an embodiment 240 of a combined illumination source 110. As depicted in FIG. 9C, a voltage provided across a cathode 248 and an anode 249 generates a plasma 244 contained by bulb 245. In addition, a LSP pump laser source 241 generates pump light 242 that is focused by focusing optics 243 to sustain plasma 244 contained by bulb 245. Plasma 244 generates broadband spectrum light over a wavelength range of ultra-violet to short infrared. Ultraviolet/visible/short infrared light 247 generated by plasma 244 exits bulb 245 through exit port 246 and is provided to the illumination optics subsystem as described with reference to FIG. 3. In addition, supercontinuum laser source 251 generates infrared light 252. Infrared light 252 is focused by focusing lens 253. Infrared light 257 from supercontinuum laser source 251 is provided to the illumination optics subsystem as described with reference to FIG. 3.

As depicted in FIG. 9C combined illumination source 110 provides ultraviolet and infrared illumination light to wafer 120 selectively. In these examples, the measurement is time multiplexed. Mirror 254 is a moveable mirror. In one example, moveable mirror 254 is mounted to a galvanometer employed to selectively direct ultraviolet/visible light 247 and infrared light 257 to wafer 120 based on whether moveable mirror 254 is locating in or out of the optical path of ultraviolet/visible light 247. In another example, a moveable total internal reflection prism is employed to selectively direct ultraviolet/visible light 247 and infrared light 257 to wafer 120. In this manner, spectral measurements including ultraviolet/visible spectra are performed at a different time than spectral measurements including infrared spectra.

In some embodiments, a spectroscopic ellipsometry based measurement system employing angle-resolved detection employs an illumination source that includes one or more spatially and temporally coherent, high-brightness illumination sources. A coherent, high-brightness illumination source enables high spectral intensity, and thus good signal to noise ratio at high throughput across the range of wavelengths from 170 nanometers to 2,000 nanometers, 170 nanometers to 2,500 nanometers, or greater.

In some embodiments, a spectroscopic ellipsometry based measurement system employing angle-resolved detection includes a spatially and temporally coherent, high-brightness supercontinuum laser illumination source and a spatially and temporally coherent, high-brightness mid-Infrared laser illumination source, e.g., a Frequency-Comb based source. The mid-IR laser illumination source generates illumination in a range of wavelengths from 5 micrometers to 15 micrometers. The combination of a supercontinuum laser source and a mid-IR laser illumination source effectively extends the spectral range of the SE based measurement system from 400 nanometers to 5-15 micrometers.

As depicted in FIG. 3, metrology system 100 includes an illumination subsystem configured to direct illumination light 101 to one or more structures formed on the wafer 120 over a range of angles of incidence and a range of azimuth angles. The illumination subsystem may include any type and arrangement of optical filter(s), polarizing component, field stop, pupil stop, etc., known in the art of spectroscopic metrology, including spectroscopic ellipsometry. As depicted in FIG. 3, the illumination subsystem includes light source 110, beam shaping optics 111, 112, 115, and 121, polarizing component 113, and pupil stop 114. As depicted, in FIG. 3, the beam of illumination light 101 is reflected from beam shaping optics 111, 112, 115, and 121 and passes through polarizing component 113 and pupil stop 114 as the beam propagates from the illumination source 110 to wafer 120. Beam 101 illuminates a portion of wafer 120 over a measurement spot 116 over a range of angles of incidence and a range of azimuth angles.

In the embodiment depicted in FIG. 1, pupil stop 114 controls the numerical aperture of the illumination at the wafer (NA_{ILL}) and may include any suitable commercially available aperture stop. In some embodiments, the illumination subsystem is configured to direct illumination light 101 to wafer 120 with an illumination Numerical Aperture (NA) of less than 0.15. In some of these embodiments, the illumination NA provides an illumination spot at wafer 120 that fits within a scribe line. This enables measurements of scribe line metrology targets. In some embodiments, illumination light 101 is focused on a 50 micrometer by 50 micrometer scribe line target area. In some embodiments, illumination light 101 is focused on a 50 micrometer by 100 micrometer scribe line target area. In some embodiments, illumination light 101 is focused on a 50 micrometer by 150 micrometer scribe line target area.

In some embodiments the numerical aperture of the illumination at the wafer (NA_{ILL}) is defined by a coherent, laser based illumination source. Although, the illumination NA may be defined by an illumination source, in general, a pupil stop may also be included in the illumination beam path from illumination source to wafer that defines the illumination NA at the wafer.

As depicted in FIG. 3, illumination light 101 is incident at measurement spot 116 over a range of angles of incidence (AOI) and a range of azimuth angles (Az). In the embodiment depicted in FIG. 3, illumination light 101 is incident at wafer 120 at over a range of angles of incidence including a nominal angle of incidence, a, at or near 65 degrees from normal incidence. In addition, illumination light 101 is incidence at wafer 120 over a range of angles of incidence. As illustrated in FIG. 3, the azimuth angle is the angle between the projection of the nominal angle of incidence on the wafer surface, depicted as the X′ axis, and a reference axis co-planar with the wafer surface, depicted as the X axis.

In addition, the illumination subsystem may include filters, masks, apodizers, etc. For example, the illumination subsystem may include an illumination field stop (not shown) and one or more optical filters (not shown). The illumination field stop controls the field of view (FOV) of the illumination subsystem and may include any suitable commercially available field stop. The optical filters are employed to control light level, spectral output, or both, from the illumination subsystem. In some examples, one or more multi-zone filters are employed as optical filters. As depicted in FIG. 1, beam shaping optics 111, 112, 115, and 121, include one or more optical elements having reflective focusing power.

In some examples, the beam size of the amount of illumination light 101 projected onto the surface of wafer 120 is smaller than a size of a measurement target that is measured on the surface of the specimen. Exemplary beam shaping techniques are described in detail in U.S. Patent Application Publication No. 2013/0114085 by Wang et al., the contents of which are incorporated herein by reference in their entirety.

In some examples, noise and polarization optimization are performed to improve the performance of illumination source 110. In some examples, depolarization is achieved by use of multimode fibers, a Hanle depolarizer, or an integration sphere. In some examples, the illumination source etendue is optimized by use of light guides, fibers, and other optical elements (e.g., lenses, curved mirrors, apodizers, etc.).

Polarizing component 113 generates the desired polarization state exiting the illumination subsystem. In some embodiments, the polarizing component includes a polarizer, a compensator, or both, and may include any suitable commercially available polarizing component. The polarizer, compensator, or both, can be fixed, rotatable to different fixed positions, or continuously rotatable. Although the illumination subsystem depicted in FIG. 1 includes one polarizing component, the illumination subsystem may include more than one polarizing component. In some embodiments, a polarizer of polarizing component 113 is a Magnesium Fluoride Rochon polarizer. In some embodiments, a compensator of polarizing component 113 includes a quartz waveplate, a Magnesium Fluoride waveplate, a Calcium Fluoride K-prism, a Calcium Fluoride double Fresnel rhomb, or any combination thereof. In some embodiments, a compensator of polarizing component 113 includes one or more waveplates. In some of these embodiments, a first waveplate includes a desired retardation over a first wavelength range and a second waveplate includes a desired retardation over a second wavelength range, etc.

Metrology system 100 also includes a collection optics subsystem configured to collect light generated by the interaction between the one or more structures and the incident illumination beam 101 over a range of collection angles of incidence and a range of collection azimuth angles. Moreover, the collection optics subsystem focuses the collected light at or near a dispersive element, e.g., a spectrometer slit, of a spectrometer. The collection optics subsystem may include any type and arrangement of optical filter(s), polarizing component, field stop, pupil stop, etc., known in the art of spectroscopic metrology. In general, a collection optics subsystem includes a field stop, a pupil mask, and one or more optical elements having reflective focusing power.

As depicted in FIG. 3, a beam of collected light 102 is collected from measurement spot 116 by a collection subsystem. Collected light 102 is reflected from beam shaping optics 129, 122, and 126, and passes through compensator 123, analyzer 124, collection mask 125, and collection field stop 103 of the collection optics subsystem as the beam of collection light 102 propagates from wafer 120 to dispersive element 127 of the spectrometer.

As depicted in FIG. 3, the collection optics subsystem includes a polarizing component that analyzes the polarization state of the collected light. In some embodiments, the polarizing component includes an analyzer, a compensator, or both, and may include any suitable commercially available polarizing component. The analyzer, compensator, or both, can be fixed, rotatable to different fixed positions, or continuously rotatable. The collection subsystem depicted in FIG. 3 includes a compensator 123 and an analyzer 124. In general, a collection optics subsystem may include any number of polarizing elements.

In some embodiments, compensator 123 includes a quartz waveplate, a Magnesium Fluoride waveplate, a Calcium Fluoride K-prism, a Calcium Fluoride double Fresnel rhomb, or any combination thereof. In some embodiments, compensator 123 includes one or more waveplates. In some of these embodiments, a first waveplate includes a desired retardation over a first wavelength range and a second waveplate includes a desired retardation over a second wavelength range, etc. In some embodiments, analyzer 124 is a Magnesium Fluoride Rochon analyzer.

As depicted in FIG. 3, the collection optics subsystem includes a collection mask 125 disposed at or near a pupil of the collection optics subsystem. Collection mask 125 includes an aperture, i.e., opening, configured to select and transmit collected light within a range of collection angles defined by a collection numerical aperture (NA). The range of collection angles corresponds to some or all of the range of angles of incidence about the nominal angle of incidence defined by the illumination NA and some or all of the range of azimuth angles.

Collection field stop 103 controls the field of view of the collection optics subsystem. In some other embodiments, a slit at or near dispersive element 127, e.g., a spectrometer slit, is employed to define the field of view of the collection optics subsystem.

In the embodiment depicted in FIG. 3, a spectrometer subsystem includes the collection field stop 103, dispersive element 127, and focusing optics 126. In some embodiments (not shown), focusing optics 126 are a set of one or more optics having reflective focusing power. The collection field stop 103 receives light from the collection optics subsystem, and transmits a portion of the collected light to dispersive element 127. Dispersive element 127 is typically located at or near an image plane of the measurement pupil. In the embodiment depicted in FIG. 1, light from collection mask 125 is imaged from collection mask 125 to the pupil plane at or near dispersive element 127.

Dispersive element 127 disperses the collected light according to wavelength over a range of wavelengths. In the embodiment depicted in FIG. 3, dispersive element 127 is a reflective grating. However, in general, any suitable dispersive element may be contemplated within the scope of this patent document. By way of non-limiting example, a dispersive element may be a reflective grating structure, a transmissive grating structure, a dispersive prism structure, etc. In some examples, a dispersive element is a planar diffraction grating. In other examples, a dispersive element is a parabolic diffraction grating.

As depicted in FIG. 3, dispersive element 127 receives light from collection mask 125 that corresponds to a range of collection angles defined by the collection NA, which, in turn, correspond to a range of angles of incidence and a range of azimuth angles. In some embodiments, dispersive element 127 is a planar diffraction grating. Dispersive element 127 disperses the collected light across the active surface of a detector in two dimensions. In some embodiments, dispersive element 127 disperses the collected light according to wavelength across the active surface of the detector along one direction, and disperses the collected light according to angle of incidence across the active surface of the detector along another direction. In some of these embodiments, the range of angles of incidence dispersed across the detector is defined by the collection NA. In other embodiments, dispersive element 127 disperses the collected light according to wavelength across the active surface of the detector along one direction, and disperses the collected light according to azimuth angle across the active surface of the detector along another direction. In some of these embodiments, the range of azimuth angles dispersed across the detector is defined by the collection NA.

As depicted in FIG. 3, metrology system 100 includes at least one detector, e.g., detector 128, having a planar, two-dimensional surface sensitive to incident light. Detector 128 is selected for signal to noise ratio performance and fast read-out. Detector 128 detects the amount of collected light and generates output signals 154 indicative of the detected light. The collected light is dispersed onto detector 128 according to wavelength along a wavelength dispersion direction of the at least one detector and according collection angle along a second direction of the at least one detector, e.g., over the range of collection angles of incidence or the range of collection azimuth angles. In a preferred embodiment, the first and second directions are orthogonal. Detector 128 resolves the collected light into discrete wavelengths along one direction and resolves the collected light into discrete collection angles along another direction.

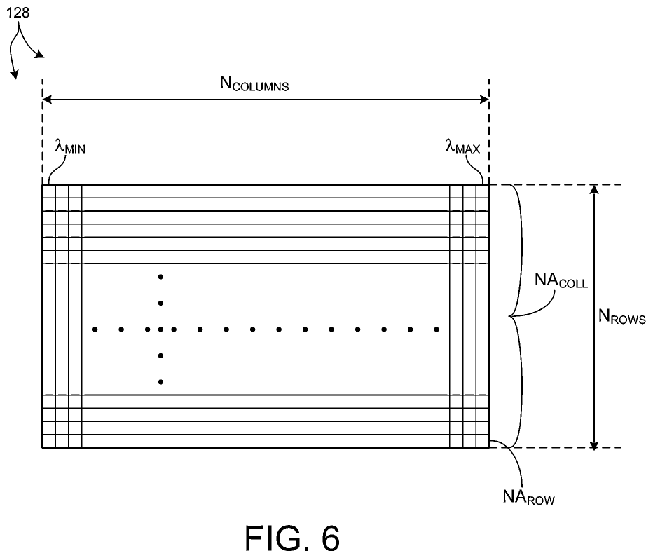

FIG. 6 is a simplified diagram illustrative of a surface of detector 128 depicted in FIG. 3. The pixels of detector 128 are arranged in a two dimensional array extending in the horizontal and vertical directions relative to the drawing page. Detector 128 includes a number of columns, N_{COLUMNS}, and a number of rows, N_{ROWS}. In some embodiments, detector 128 includes 1,000-5,000 columns and 100-200, or more, rows. As illustrated in FIG. 3, collected light is dispersed across detector 128 in the horizontal direction, from the smallest resolved wavelength, λmin, to the largest resolved wavelength, λmax. In addition, the collected light is dispersed across the detector according to angle of incidence (or azimuth angle) in the vertical direction. The full collection NA (NA_{COLL}) spans the detector surface in the vertical direction. The NA associated with each row of detector 128 (NA_{ROW}) is the collection NA divided by the number of rows of detector 128 spanned by the collection NA.

In a further aspect, a spectroscopic metrology system includes a positioning subsystem configured to rotate the dispersive element about a first axis in-plane with the planar, two-dimensional surface of the at least one detector and aligned with a blaze direction of the dispersive element and rotate the dispersive element about a second axis in-plane with the planar, two-dimensional surface of the at least one detector and orthogonal to the first axis.

As depicted in FIG. 3, dispersive element 127 is located in the optical path from of the collection optics. In addition, dispersive element 127 is mechanically coupled to a positioning subsystem 136 configured to change the orientation of dispersive element 127 in accordance with command signals 135 communicated from computing system 130 to positioning subsystem 136. In some embodiments, positioning subsystem 136 is a tip/tilt stage, e.g., galvanometer stage, capable of changing the orientation of dispersive element 127. In some embodiments, positioning subsystem 136 reorients the dispersive element 127 such that dispersive element 127 scans through the collection NA over the range of collection AOI or AZ, and scans the dispersed beam onto detector 128, e.g., in the AOI or Az scanning direction depicted in FIG. 3. In the example depicted in FIG. 3., positioning subsystem 136 scans dispersive element 127 about the X″ axis to scan through the collection NA over the range of collection AOI and projects the scanned range of AOIs across detector 128 in the vertical direction. In this manner, each image detected by detector 128 includes photon intensity data resolved in wavelength in the X-direction and AOI in the Y-direction.

In a further aspect, a spectroscopic metrology system is configured to generate a set of multiple images indicative of the detected light resolved in wavelength, AOI, and Az. In the embodiment depicted in FIG. 3, detector 128, each image detected by detector 128 includes photon intensity data resolved in wavelength in the X-direction and AOI in the Y-direction. In addition, positioning subsystem 136 reorients dispersive element 127 about the Y″ axis to sample a set of different azimuth angles over the range of collection azimuth angles. An image is detected by detector 128 at each different azimuth angle, and each detected image captures photon intensity data resolved in wavelength in the X-direction and AOI in the Y-direction as described hereinbefore. In this manner, spectroscopic metrology system collects a set of images that resolve light scattered from measurement spot 116 in wavelength, AOI, and Az.

As depicted in FIG. 3, positioning subsystem 136 rotates dispersive element 127 about one axis, e.g., the X″ axis, to scan through the collection NA over the range of collection AOI and rotates dispersive element 127 about an orthogonal axis, e.g., the Y″ axis, to capture a set of images each associated with a different Az. In general, however, many other configurations may be contemplated within the scope of this patent document. For example, a spectroscopic metrology system may be configured to scan through the range of Az and step through the range of AOI to capture the set of measurement images resolved in wavelength, AOI, and Az. In some other embodiments, dispersive element 127 may be designed with a broad entrance angle that simultaneously disperses the collected light according to wavelength in one direction and according to AOI (or Az) in the orthogonal direction. In these embodiments, positioning subsystem 136 is configured to step through Az (or AOI) about one rotational axis only, rather than two rotational axes.

In general, positioning subsystem 136 may be configured to orient dispersive element 127 about one axis or two orthogonal axes using any suitable combination of mechanisms and actuators. By way of non-limiting example, positioning subsystem 127 may include a gimbal mechanism actuated by piezoelectric actuators, Lorentz coil actuators, rotary motors, etc., a flexure mechanism actuated by linear actuators such as piezoelectric actuators or Lorentz coil actuators, a hexapod mechanism actuated by linear actuators such as piezoelectric actuators, etc.

Metrology system 100 also includes computing system 130 configured to receive detected signals 154 including the set of multiple images associated with the amount of collected light resolved over the range of angles of incidence, the range of azimuth angles, and the range of wavelengths, and determine an estimate 155 of a value of a parameter of interest characterizing a structural characteristic of the measured structure(s) based on the detected images.

In some embodiments, computing system 130 estimates values of one or more parameters of interest by regression on a physics-based measurement model. In other embodiments, computing system 130 estimates values of one or more parameters of interest based on a trained machine learning based measurement model.

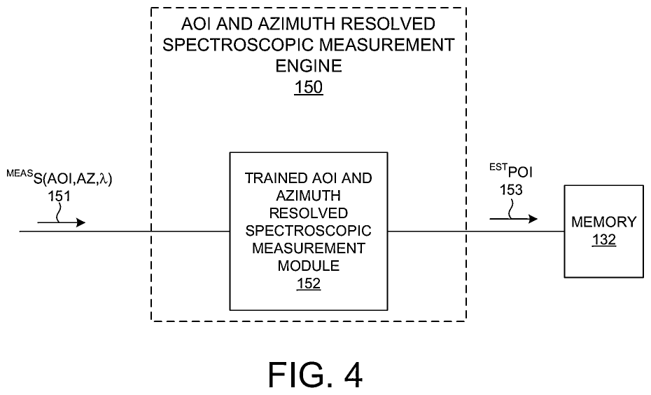

FIG. 4 is a diagram illustrative of an AOI and Az resolved spectroscopic measurement engine 150 in one embodiment. The AOI and Az resolved spectroscopic measurement engine 150 includes a trained AOI and Azimuth resolved spectroscopic measurement model 152. As depicted in FIG. 4, a set of measured spectral images resolved in wavelength, AOI, and Az, ^{MEAS}S (AOI, Az, λ) 151, are provided as input to trained AOI and Azimuth resolved spectroscopic measurement model 152. In response, trained AOI and Azimuth resolved spectroscopic measurement model 152 estimates the value of a parameter of interest characterizing a structural characteristic of the specimen under measurement, ^{EST}POI 153, based on the set of measured spectral images.

In a further aspect, a machine learning based AOI and Az resolved spectroscopic measurement model is trained based on multiple Design Of Experiments (DOE) measurements.

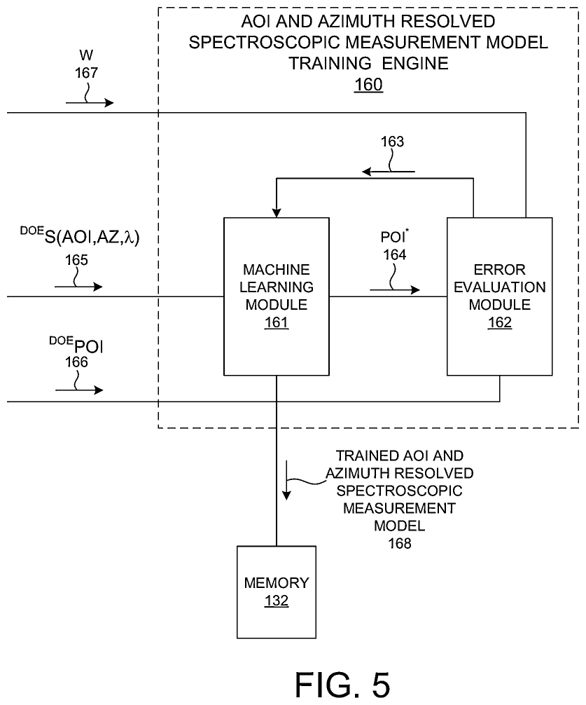

FIG. 5 is a diagram illustrative of an AOI and Az resolved spectroscopic measurement model training engine 160 implemented on any suitable computing system, e.g., computing system 130. As depicted in FIG. 5, an AOI and Az resolved spectroscopic measurement model training engine 160 includes a machine learning module 161 and an error evaluation module 162. Training data is communicated to AOI and Az resolved spectroscopic measurement model training engine 160. The training data includes a large number of DOE measurements including multiple images associated with an amount of collected light over a range of angles of incidence, a range of azimuth angles, and a range of wavelengths, ^{DOE}S (AOI, AZ, λ) 165, and a corresponding DOE value of the parameter of interest, ^{DOE}POI 166.

As depicted in FIG. 5, training data set 165 including multiple sets of collected images is communicated to machine learning module 161, and corresponding training data set 166 including corresponding values of a parameter of interest is communicated to error evaluation module 162.

In some examples, machine learning module 161 generates estimated values of one or more parameters of interest, POI* 164, based on each set of DOE images comprising the training data set 165. Error evaluation module 162 receives the estimated values of the one or more parameters of interest, POI* 164, generated by machine learning module 161. In addition, error evaluation module 162 receives training data set 166 including the corresponding values of the parameter of interest characterizing associated with each set of DOE images included in training data set 165. The values of training set 166 indicate trusted values of the one or more parameters of interest associated with each set of DOE images included in training data set 165. Error evaluation module 162 generates updated values of weighting parameters 163 of the machine learning model 161 undergoing training to minimize differences between the estimated values of the one or more parameters of interest, POI* 164, and the trusted values of the one or more parameters of interest associated with each set of measurement signals. In the next iteration of model training, new estimated values of the one or more parameters of interest, POI* 164, are generated by machine learning module 161 based on the values of the weighting parameters 163 generated in the previous iteration. The training process continues until the differences between the estimated values of the one or more parameters of interest, POI* 164, and the trusted values of the one or more parameters of interest associated with each set of measurement signals are acceptably small. At this point, the trained AOI and Az resolved spectroscopic measurement model 168 is stored in a memory, e.g., memory 132.

In some embodiments, training data set 165 includes measured images associated with a measurement of each of the plurality of instances of the semiconductor structure under measurement by a spectroscopic metrology system, such as system 100, and training data set 166 includes a corresponding measured value of the parameter of interest associated with a reference measurement of each of the plurality of instances of the semiconductor structure by a reference metrology system. Typically, the sets of measured images and corresponding reference measurements are derived from measurements of instances of the structure of interest fabricated on one or more Design Of Experiments (DOE) wafers. The DOE wafers are typically off-line wafers purposely fabricated with variations in process parameters to probe the expected process space and ensure that the measurement model is trained to reliably perform measurements of structures fabricated within the expected process window during high volume production.

For many process steps of a complex semiconductor structure, reliable, actual reference measurements are only available from low throughput, expensive, and often destructive measurement techniques, e.g., Transmission Election Microscopy (TEM), Scanning Electron Microscopy (SEM), etc. Thus, in practice, it is not feasible to generate very large reference data sets based on actual reference measurement data generated by trustworthy reference measurement systems for many process steps. In response, synthetically generated measurement data, i.e., generated by simulation, are employed to overcome the lack of actual reference measurement data collected at a limited number of different locations on a limited number of different wafers.

In a further aspect, AOI and Az resolved spectroscopic measurement model training engine 160 includes a weighting module (not shown) that assigns different weighting values to different sets of training data, e.g., any of the different set of training data depicted in FIG. 5. The relative weighting of different sets of training data emphasizes training data sets assigned a relatively high weighting and deemphasizes training data sets assigned a relatively low weighting. In this manner, training data sets associated with a higher level of trust in the data or higher correlation to the current version of the structure of interest in the present state are emphasized over training data sets that are less trusted or have lower correlation to the current version of the structure of interest in the present state.

In the example, depicted in FIG. 5, weighting values, W 167, are communicated to error evaluation module 162. In one example, actual reference measurement values, and corresponding measured images associated with measurement of the reference structures by a spectroscopic metrology system are assigned a relatively high weighting compared to synthetic training data for purposes of training. In general, any relative weighting among the training data sets may be contemplated within the scope of this patent document.

In a further aspect, a subset of each image of a set of measured images resolved in AOI, Az, and wavelength is selected as input to a measurement model employed to estimate a value of a parameter of interest. In some examples, the subset of each image is selected to capture signal information associated with a smaller NA than the available NA associated with the entire collected image. It may be preferable to estimate values of one or more parameters of interest based on signal information associated with a smaller NA to effectively reduce the illumination spot size to fit smaller measurement targets.

Spectroscopic ellipsometry measurements of semiconductor structures resolved in AOI, AZ, and wavelength enable critical dimension measurements, shape and profile measurements, and film measurements of deep structures fabricated in accordance with current semiconductor fabrication nodes and those contemplated for fabrication at future semiconductor fabrication nodes. By way of non-limiting example, spectroscopic ellipsometry measurements of semiconductor structures resolved in AOI, AZ, and wavelength enable measurements of features of 3D NAND memory structures having more than 300 layers, e.g., 300-1,000 layers, 3D DRAM memory structures greater than 10 micrometers deep, CMOS-based image sensors, power devices, semiconductor bonding through-silicon-via (TSV) structures, and micro-electro-mechanical structures (MEMS) with deep trenches and holes, e.g., 20 millimeter, or deeper, 100 millimeters, or deeper, etc.

In some embodiments, the methods and systems for spectroscopic metrology of semiconductor devices described herein are applied to the measurement of high aspect ratio (HAR), large lateral dimension structures, opaque film layers, or a combination thereof. These embodiments enable optical critical dimension (CD), film, and composition metrology for semiconductor devices with HAR structures (e.g., NAND, VNAND, TCAT, DRAM, etc.) and, more generally, for complex devices that suffer from low light penetration into the structure(s) being measured. HAR structures often include hard mask layers to facilitate etch processes for HARs. As described herein, the term “HAR structure” refers to any structure characterized by an aspect ratio that exceeds 2:1 or 10:1, and may be as high as 100:1, or higher.

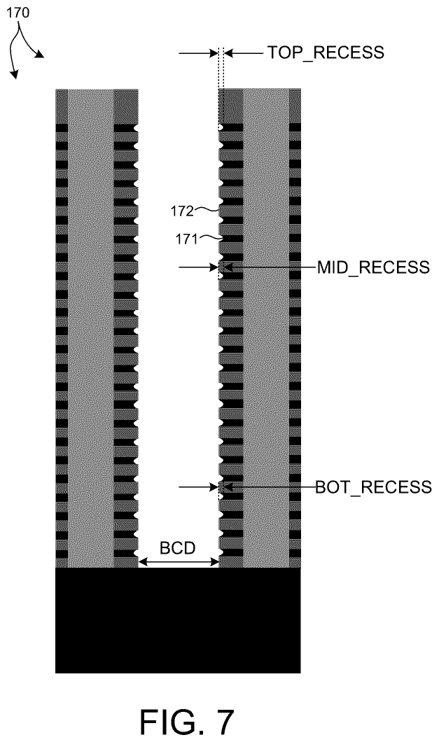

FIG. 7 depicts a vertically integrated memory structure 170 including tungsten layers 161 sandwiched between oxide layers 172. As depicted in FIG. 7, the etching process leaves behind a horizontal recess in each tungsten layer 171 relative to oxide layers 172 above and below each tungsten layer 171. The tungsten recess at or near the top of structure 170 is referred to as a top recess. The tungsten recess at or near the middle of structure 170 is referred to as a mid recess. The tungsten recess at or near the bottom of structure 170 is referred to as a bot recess. The opening of the oxide layer 172 at or near the bottom of structure 170 is referred to as the bottom critical dimension (BCD).

In some embodiments, a spectroscopic measurement system includes a combined illumination source including a supercontinuum laser illumination source and a MID-IR laser illumination source. The combined illumination source generates illumination light having wavelengths down to 400 nanometers. In some examples, the combined illumination source generates illumination light having wavelengths up to and including 4.2 micrometers. In some examples, the combined illumination source generates illumination light having wavelengths up to and including 5 micrometers. In some examples, the combined illumination source generates illumination light having wavelengths that exceed 5micrometers. Furthermore, the spectroscopic measurement system includes one or more measurement channels spanning the range of illumination wavelengths employed to perform measurements of semiconductor structures. The one or more measurement channels are operable in parallel (i.e., simultaneous measurement of the sample throughout the wavelength range) or in sequence (i.e., sequential measurement of the sample throughout the wavelength range).

In general, a collection optics subsystem may direct light to more than one detector. In these embodiments, two or more detectors are each configured to detect collected light over different wavelength ranges, simultaneously.

In one example, one detector is a charge coupled device (CCD) sensitive to ultraviolet and visible light (e.g., light having wavelengths between 190 nanometers and 860 nanometers), and another detector is a photo detector array (PDA) sensitive to infrared light (e.g., light having wavelengths between 950 nanometers and 5000 nanometers). However, in general, other two dimensional detector technologies may be contemplated (e.g., a position sensitive detector (PSD), an infrared detector, a photovoltaic detector, etc.). Each detector converts the incident light into electrical signals indicative of the spectral intensity of the incident light. In some embodiments, the detection subsystem is arranged such that the collected light propagates to all detectors of metrology system 100, simultaneously. By simultaneously collecting UV and IR spectra, measurement times are reduced and all spectra are measured with the same alignment conditions. This allows wavelength errors to be corrected more easily because a common correction can be applied to all spectral data sets.

In general, dispersive element 127 may be configured to subdivide the incident light into different wavelength bands, propagate the different wavelength bands in different directions, and disperse the light of one of the wavelength bands onto one or more detectors in any suitable manner. In one example, dispersive element 127 is configured as a transmissive grating. In some other examples, dispersive element 127 includes a beamsplitting element to subdivide the beam into different wavelength bands and a reflective or transmissive grating structure to disperse one of the wavelength bands onto a detector.

In some embodiments, dispersive element 127 is a reflective grating configured to diffract a subset of wavelengths of the incident light into the +/−1 diffraction order toward one detector and diffract a different subset of wavelengths of the incident light into the zero diffraction order toward another detector.

By measuring a target with infrared, visible, and ultraviolet light in a single system, precise characterization of complex three dimensional structures is enabled. In general, relatively long wavelengths penetrate deep into a structure and provide suppression of high diffraction orders when measuring structures with relatively large pitch. Relatively short wavelengths provide precise dimensional information about structures such as relatively small CD and roughness features. In some examples, longer wavelengths enable measurement of dimensional characteristics of targets with relatively rough surfaces or interfaces due to lower sensitivity of longer wavelengths to roughness. In general, measuring a target with infrared, visible, and ultraviolet light in a single system improves sensitivity to some measurement parameters and reduces correlations among parameters (e.g., parameters characterizing top and bottom layers).

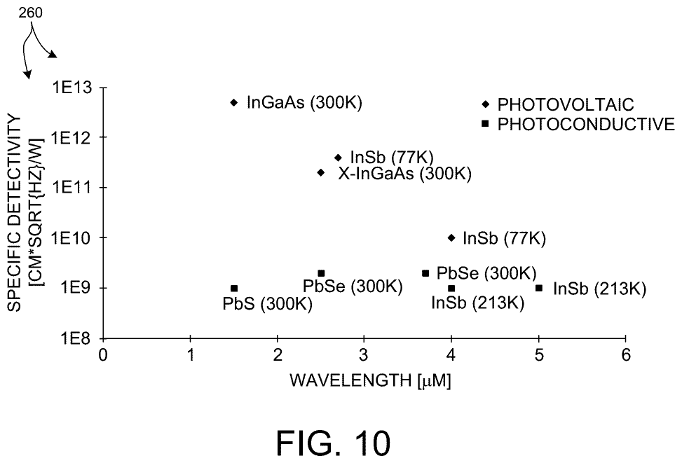

FIG. 10 depicts a plot 260 illustrative of the specific detectivity of various detector technologies operating at specified temperatures. As illustrated in FIG. 10, both photovoltaic and photoconductive detector technologies are suitable for detecting radiation at infrared wavelengths exceeding one micrometer, and up to five micrometers. In some examples, metrology system 100 include detectors such as lead sulfide (PbS), lead selenide (PbSe), indium antimonide (InSb), indium arsenide (InAs), mercury cadmium telluride (HgCdTe), indium gallium arsenide (InGaAs), x-InGaAs, pyroelectric, and bolometric detectors.

Pyroelectric and bolometric detectors are not quantum detectors. Thus, these detectors may accept high light levels without saturation, and thus reduce noise sensitivity.

In some embodiments, the detector subsystem is shot noise limited, rather than dark noise limited. In these examples, it is preferred to perform multiple measurements at high light levels to reduce measurement system noise.

In some embodiments, a time dependent measurement (e.g., pulsed light source, chopper, etc.) is performed in coordination with a lock-in amplifier or other phase locked loop to increase the measurement signal to noise ratio.

In some embodiments, one or more of the detectors are cooled to temperatures of −20° C., 210° K, 77° K, or other low temperature to reduce measurement noise. In general, any suitable cooling element may be employed to maintain the temperature of a detector at a constant temperature during operation. By way of non-limiting example, any of a multi stage Peltier cooler, rotating disc cooler, Stirling cycle cooler, N2 cooler, He cooler, etc. may be contemplated within the scope of this patent document.

In some embodiments, a broad range of wavelengths are detected by a detector that includes multiple photosensitive areas having different sensitivity characteristics. Collected light is linearly dispersed across the surface of the detector according to wavelength in one direction and according to angle of incidence in another direction. Each different photosensitive area is arranged on the detector to sense a different range of incident wavelengths. In this manner, a broad range of wavelengths are detected with high signal to noise ratio by a single detector. These features, individually, or in combination, enable high throughput measurements of high aspect ratio structures (e.g., structures having depths of one micrometer or more) with high throughput, precision, and accuracy.

In some embodiments, a detector subsystem includes a multi-zone infrared detector that combines different sensitivity bands at different locations on a single detector package. The detector is configured to deliver a continuous spectrum of data at different sensitivities, depending on location of incidence.

FIG. 12 illustrates typical photosensitivity curves of available Indium Gallium Arsenide (InGaAs) sensors. As depicted in FIG. 12, no single sensor of the available InGaAs sensors is capable of providing adequate photosensitivity across a wavelength band from 1 micrometer to 2.5 micrometers. Thus, individually, the available sensors are only capable of sensing over a narrow waveband.

In some embodiments, multiple sensor chips, each sensitive in a different waveband are combined into a single detector package. In turn, this multi-zone detector is implemented in the metrology systems described herein.

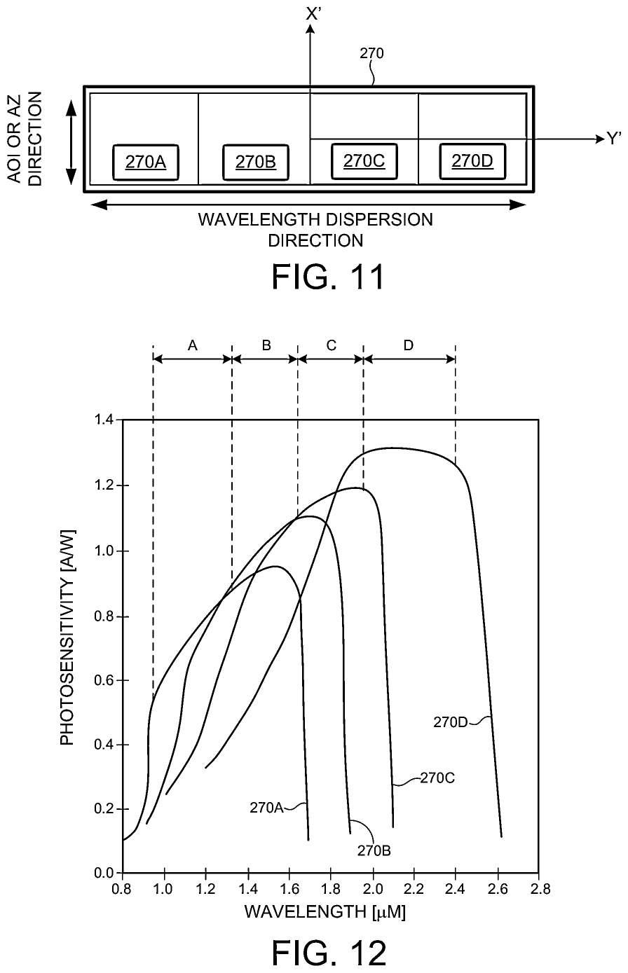

FIG. 11 depicts four sensor chips 270A-D derived from four different wavebands to make a multi-zone infrared detector 180. The four sensor chips include different material compositions that each exhibit different photosensitivity characteristics. As depicted in FIG. 11, sensor chip 270A exhibits high sensitivity over a waveband, A, sensor chip 270B exhibits high sensitivity over a waveband, B, sensor chip 270C exhibits high sensitivity over a waveband, C, and sensor chip 270D exhibits high sensitivity over a waveband, D. A metrology system incorporating detector 270 is configured to disperse wavelengths within waveband A onto sensor chip 270A, disperse wavelengths within waveband B onto sensor chip 270B, disperse wavelengths within waveband C onto sensor chip 270C, and disperse wavelengths within waveband D onto sensor chip 270D. In this manner, high photosensitivity (i.e., high SNR) is achieved over the aggregate waveband that includes wavebands A-D from a single detector. As a result measurement noise over the entire measurement range is reduced by limiting the use of a particular sensor to a narrowband where measurement sensitivity is high and measurement noise is low.

In some examples, a multi-zone detector includes InGaAs sensors with sensitivity to different spectral regions assembled in a single sensor package to produce a single, continuous spectrum covering wavelengths from 750 nanometers to 3,000 nanometers, or beyond.

In general, any number of individual sensors may be assembled along the direction of wavelength dispersion of the multi-zone detector such that a continuous spectrum maybe derived from the detector. However, typically, two to four individual sensors are employed in a multi-zone detector, such as detector 270.

In one embodiment, three individual sensors are employed with the first segment spanning the range between 800 nanometers and 1600 nanometers, the second segment spanning the range between 1600 nanometers and 2200 nanometers, and the third segment spanning the range between 2200 nanometers and 2600 nanometers.

Although, the use of InGaAs based infrared detectors is specifically described herein, in general, any suitable material that exhibits narrow sensitivity ranges and sharp sensitivity cutoffs may be integrated into a multi-zone detector as described herein.

As depicted in FIG. 3, the illustrated measurement channel includes a polarizer on the illumination side and an analyzer on the collection side. However, in general, it is contemplated that any measurement channel may include, or not include, an illumination polarizer, a collection analyzer, an illumination compensator, a collection compensator, in any combination, to perform measurements of the polarized reflectivity of the sample, unpolarized reflectivity of the sample, or both.

In general, metrology system 100 utilizes one or more coherent illumination sources in one or more spectroscopic ellipsometers, spectroscopic reflectometers, discrete wavelength ellipsometers, rotating polarizer ellipsometers, rotating compensator ellipsometers, rotating polarizer rotating compensator ellipsometers, Mueller-matrix ellipsometers, or any combination thereof.

In another further aspect, the dimensions of illumination pupil stop and the dimensions of the collection mask are adjusted to optimize the resulting measurement accuracy and speed based on the nature of target under measurement.

In another further aspect, the dimensions of illumination field stop are adjusted to achieve the desired spectral resolution for each measurement application.

In some examples, e.g., if the sample is a very thick film or grating structure, the illumination field stop projected on wafer plane in the direction perpendicular to the plane of incidence is adjusted to reduce the field size to achieve increase spectral resolution. In some examples, e.g., if the sample is a thin film, the illumination field stop projected on wafer plane in the direction perpendicular to the plane of incidence is adjusted to increase the field size to achieve a shortened measurement time without losing spectral resolution.

In the embodiment depicted in FIG. 3, computing system 130 is configured to receive signals 154 indicative of the detected images. Computing system 130 is further configured to determine control signals 119 that are communicated to programmable illumination field stop 117. Programmable illumination field stop 117 receives control signals 119 and adjusts the size of the illumination aperture to achieve the desired illumination field size.

In some examples, the illumination field stop is adjusted to optimize measurement accuracy and speed as described hereinbefore. In another example, the illumination field stop is adjusted to prevent image clipping by the spectrometer slit and corresponding degradation of measurement results. In this manner, the illumination field size is adjusted such that the image of the measurement target underfills the spectrometer slit. In one example, the illumination field stop is adjusted such that the projection of the polarizer slit of the illumination optics underfills the spectrometer slit of the metrology system. In another example, the illumination field stop is adjusted such that the projection of the polarizer slit of the illumination optics overfills the spectrometer slit of the metrology system.

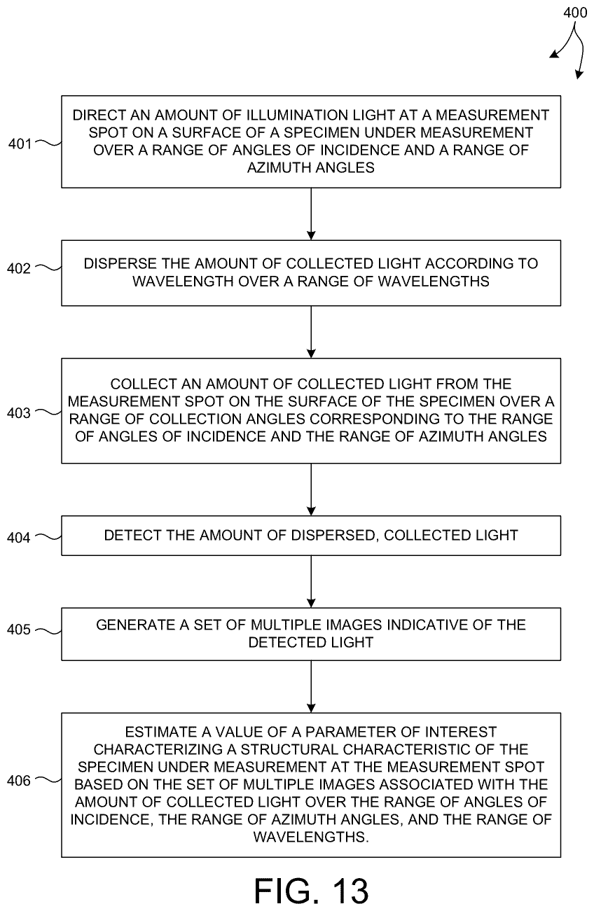

FIG. 13 illustrates a method 400 of performing spectroscopic measurements resolved in wavelength, AOI, and Az, in at least one novel aspect. Method 400 is suitable for implementation by a metrology system such as metrology system 100 illustrated in FIG. 3, of the present invention. In one aspect, it is recognized that data processing blocks of method 400 may be carried out via a pre-programmed algorithm executed by one or more processors of computing system 130, or any other general purpose computing system. It is recognized herein that the particular structural aspects of metrology system 100 do not represent limitations and should be interpreted as illustrative only.

In block 401, an amount of illumination light is directed at a measurement spot on a surface of a specimen under measurement over a range of angles of incidence and a range of azimuth angles.

In block 402, an amount of collected light is collected from the measurement spot on the surface of the specimen over a range of collection angles corresponding to the range of angles of incidence and the range of azimuth angles.

In block 403, the amount of collected light is dispersed according to wavelength over a range of wavelengths.

In block 404, the amount of dispersed, collected light is detected.

In block 405, a set of multiple images indicative of the detected light is generated.

In block 406, a value of a parameter of interest characterizing a structural characteristic of the specimen under measurement at the measurement spot is estimated based on the set of multiple images associated with the amount of collected light over the range of angles of incidence, the range of azimuth angles, and the range of wavelengths.

In a further embodiment, system 100 includes one or more computing systems 130 employed to perform measurements of actual device structures based on spectroscopic measurement data collected in accordance with the methods described herein. The one or more computing systems 130 may be communicatively coupled to the spectrometer. In one aspect, the one or more computing systems 130 are configured to receive measurement data associated with measurements of the structure of the specimen under measurement.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers in any manner known in the art. For example, the one or more computing systems 130 may be coupled to computing systems associated with the spectrometers. In another example, the spectrometers may be controlled directly by a single computer system coupled to computer system 130.

The computer system 130 of metrology system 100 may be configured to receive and/or acquire data or information from the subsystems of the system (e.g., spectrometers and the like) by a transmission medium that may include wireline and/or wireless portions. In this manner, the transmission medium may serve as a data link between the computer system 130 and other subsystems of system 100.

Computer system 130 of metrology system 100 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board metrology system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value 155 determined by computer system 130 may be communicated and stored in an external memory. In this regard, measurement results may be exported to another system.

Computing system 130 may include, but is not limited to, a personal computer system, mainframe computer system, workstation, image computer, parallel processor, cloud based computing system, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In some examples, the measurement models are implemented as an element of a SpectraShape® optical critical-dimension metrology system available from KLA-Tencor Corporation, Milpitas, California, USA. In this manner, the model is created and ready for use immediately after the spectra are collected by the system.

In some other examples, the measurement models are implemented off-line, for example, by a computing system implementing AcuShape® software available from KLA-Tencor Corporation, Milpitas, California, USA. The resulting, trained model may be incorporated as an element of an AcuShape® library that is accessible by a metrology system performing measurements.

In another aspect, the methods and systems for spectroscopic metrology of semiconductor devices described herein are applied to the measurement of high aspect ratio (HAR) structures, large lateral dimension structures, or both. The described embodiments enable optical critical dimension (CD), film, and composition metrology for semiconductor devices including three dimensional NAND structures, such as vertical-NAND (V-NAND) structures, dynamic random access memory structures (DRAM), etc., manufactured by various semiconductor manufacturers such as Samsung Inc. (South Korea), SK Hynix Inc. (South Korea), Toshiba Corporation (Japan), and Micron Technology, Inc. (United States), etc. These complex devices suffer from low light penetration into the structure(s) being measured. FIG. 7 depicts an exemplary high aspect ratio structure 170 that suffers from low light penetration into the structure(s) being measured. A spectroscopic ellipsometer with broadband capability and wide ranges of AOI and azimuth angle having simultaneous spectral band detection as described herein is suitable for measurements of these high-aspect ratio structures. HAR structures often include hard mask layers to facilitate etch processes for HARs. As described herein, the term “HAR structure” refers to any structure characterized by an aspect ratio that exceeds 2:1 or 10:1, and may be as high as 100:1, or higher.

In yet another aspect, the measurement results described herein can be used to provide active feedback to a process tool (e.g., lithography tool, etch tool, deposition tool, etc.). For example, values of measured parameters determined based on measurement methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values and a trained measurement model may be communicated to a lithography tool, etch tool, or deposition tool.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, tilt or center of line (CLS) shift metrology, critical dimension and pitch distortion metrology, focus/dosage metrology, film thickness metrology, and composition metrology. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from angle resolved collection NA.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous Si02. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A spectroscopic metrology system comprising:
one or more illumination sources configured to generate an amount of illumination light, the amount of illumination light incident at a measurement spot on a surface of a specimen under measurement over a range of angles of incidence and a range of azimuth angles;
a collection optics subsystem configured to collect an amount of collected light from the measurement spot on the surface of the specimen over a range of collection angles corresponding to the range of angles of incidence and the range of azimuth angles;
a dispersive element having an incidence surface located in an optical path of the collection optics subsystem at or near an image plane of the measurement pupil, wherein the dispersive element disperses the amount of collected light according to wavelength over a range of wavelengths; and
at least one detector having a planar, two-dimensional surface sensitive to incident light, the at least one detector configured to detect the amount of collected light dispersed by the dispersive element and generate a set of multiple images indicative of the detected light; and
a computing system configured to estimate a value of a parameter of interest characterizing a structural characteristic of the specimen under measurement at the measurement spot based on the set of multiple images associated with the amount of collected light over the range of angles of incidence, the range of azimuth angles, and the range of wavelengths.

2. The spectroscopic metrology system of claim 1, wherein each image of the set of multiple images is indicative of a portion of the amount of collected light associated with a different angle of incidence, and wherein each image of the set of multiple images is indicative of the amount of collected light dispersed onto the at least one detector according to wavelength over the range of wavelengths along a first direction of the at least one detector and according to azimuth angle over the range of azimuth angles along a second direction of the at least one detector, or
each image of the set of multiple images is indicative of a portion of the amount of collected light associated with a different azimuth angle, and wherein each image of the set of multiple images is indicative of the amount of collected light dispersed onto the at least one detector according to wavelength over the range of wavelengths along a first direction of the at least one detector and according to angle of incidence over the range of angles of incidence along a second direction of the at least one detector.

3. The spectroscopic metrology system of claim 1, wherein the estimating of the value of the parameter of interest characterizing the structural characteristic of the specimen under measurement involves a trained angle of incidence (AOI) and azimuth angle (AZ) resolved spectroscopic measurement model, wherein the trained AOI and AZ resolved spectroscopic measurement model generates the estimated value of the parameter of interest in response to the set of multiple images provided as input to the trained AOI and AZ resolved spectroscopic measurement model.

4. The spectroscopic metrology system of claim 3, wherein the trained AOI and AZ resolved spectroscopic measurement model is trained based on multiple Design Of Experiments (DOE) measurements, each DOE measurement including a training set of multiple images associated with an amount of collected light over the range of angles of incidence, the range of azimuth angles, and the range of wavelengths and a corresponding DOE value of the parameter of interest.

5. The spectroscopic metrology system of claim 1, further comprising:
a positioning subsystem configured to rotate the dispersive element about a first axis in-plane with the planar, two-dimensional surface of the at least one detector and aligned with a blaze direction of the dispersive element and rotate the dispersive element about a second axis in-plane with the planar, two-dimensional surface of the at least one detector and orthogonal to the first axis.

6. The spectroscopic metrology system of claim 5, wherein the positioning subsystem includes any of a gimbal stage, a piezoelectric stage, and a Lorentz coil stage.

7. The spectroscopic metrology system of claim 1, wherein the dispersive element is a reflective grating structure, a transmissive grating structure, or a dispersive prism structure.

8. The spectroscopic metrology system of claim 1, wherein the at least one detector includes two or more detectors, wherein each of the two or more detectors detects a portion of the amount of collected light over different spectral ranges.

9. The spectroscopic metrology system of claim 8, wherein each of the two or more detectors detects each portion of the amount of collected light over different spectral ranges simultaneously.

10. The spectroscopic metrology system of claim 1, wherein the at least one detector includes two or more different surface areas each having different photosensitivity, wherein the two or more different surface areas are aligned with a direction of wavelength dispersion across the surface of the at least one detector.

11. The spectroscopic metrology system of claim 1, wherein the specimen under measurement includes a three dimensional NAND structure or a dynamic random access memory (DRAM) structure.

12. A method comprising:
directing an amount of illumination light at a measurement spot on a surface of a specimen under measurement over a range of angles of incidence and a range of azimuth angles;
collecting an amount of collected light from the measurement spot on the surface of the specimen over a range of collection angles corresponding to the range of angles of incidence and the range of azimuth angles;
dispersing the amount of collected light according to wavelength over a range of wavelengths;
detecting the amount of dispersed, collected light;
generating a set of multiple images indicative of the detected light; and
estimating a value of a parameter of interest characterizing a structural characteristic of the specimen under measurement at the measurement spot based on the set of multiple images associated with the amount of collected light over the range of angles of incidence, the range of azimuth angles, and the range of wavelengths.

13. The method of claim 12, wherein each image of the set of multiple images is indicative of a portion of the amount of collected light associated with a different angle of incidence, and wherein each image of the set of multiple images is indicative of the amount of collected light dispersed onto the at least one detector according to wavelength over the range of wavelengths along a first direction of the at least one detector and according to azimuth angle over the range of azimuth angles along a second direction of the at least one detector, or
each image of the set of multiple images is indicative of a portion of the amount of collected light associated with a different azimuth angle, and wherein each image of the set of multiple images is indicative of the amount of collected light dispersed onto the at least one detector according to wavelength over the range of wavelengths along a first direction of the at least one detector and according to angle of incidence over the range of angles of incidence along a second direction of the at least one detector.

14. The method of claim 12, wherein the estimating of the value of the parameter of interest characterizing the structural characteristic of the specimen under measurement involves generating the estimated value of the parameter of interest in response to the set of multiple images provided as input to a trained AOI and AZ resolved spectroscopic measurement model.

15. The method of claim 14, further comprising:
training the AOI and AZ resolved spectroscopic measurement model based on multiple Design Of Experiments (DOE) measurements, each DOE measurement including a training set of multiple images associated with an amount of collected light over the range of angles of incidence, the range of azimuth angles, and the range of wavelengths and a corresponding DOE value of the parameter of interest.

16. The method of claim 12, further comprising:
rotating the dispersive element about a first axis in-plane with the planar, two-dimensional surface of the at least one detector and aligned with a blaze direction of the dispersive element; and
rotating the dispersive element about a second axis in-plane with the planar, two-dimensional surface of the at least one detector and orthogonal to the first axis.

17. The method of claim 12, wherein the dispersive element is a reflective grating structure, a transmissive grating structure, or a dispersive prism structure.

18. The method of claim 12, wherein the specimen under measurement includes a three dimensional NAND structure or a dynamic random access memory (DRAM) structure.

19. A spectroscopic metrology system comprising:
one or more illumination sources configured to generate an amount of illumination light, the amount of illumination light incident at a measurement spot on a surface of a specimen under measurement over a range of angles of incidence and a range of azimuth angles;
a collection optics subsystem configured to collect an amount of collected light from the measurement spot on the surface of the specimen over a range of collection angles corresponding to the range of angles of incidence and the range of azimuth angles;
a dispersive element having an incidence surface located in an optical path of the collection optics subsystem at or near an image plane of the measurement pupil, wherein the dispersive element disperses the amount of collected light according to wavelength over a range of wavelengths; and
at least one detector having a planar, two-dimensional surface sensitive to incident light, the at least one detector configured to detect the amount of collected light dispersed by the dispersive element and generate a set of multiple images indicative of the detected light; and
a non-transitory, computer-readable medium storing instructions that, when executed by one or more processors, causes the one or more processors to:
estimate a value of a parameter of interest characterizing a structural characteristic of the specimen under measurement at the measurement spot based on the set of multiple images associated with the amount of collected light over the range of angles of incidence, the range of azimuth angles, and the range of wavelengths.

20. The spectroscopic metrology system of claim 19, wherein each image of the set of multiple images is indicative of a portion of the amount of collected light associated with a different angle of incidence, and wherein each image of the set of multiple images is indicative of the amount of collected light dispersed onto the at least one detector according to wavelength over the range of wavelengths along a first direction of the at least one detector and according to azimuth angle over the range of azimuth angles along a second direction of the at least one detector, or
each image of the set of multiple images is indicative of a portion of the amount of collected light associated with a different azimuth angle, and wherein each image of the set of multiple images is indicative of the amount of collected light dispersed onto the at least one detector according to wavelength over the range of wavelengths along a first direction of the at least one detector and according to angle of incidence over the range of angles of incidence along a second direction of the at least one detector.
